(19) United States
(12) Patent Application Publication
(10) Pub. No.: US 2015/0365085 A1
(43) Pub. Date: Dec. 17, 2015

(54) Dual Pull-Down Control Module, Shift Register Unit, Gate Driver, and Display Panel

(71) Applicants: BOE TECHNOLOGY GROUP CO., LTD., Beijing (CN); Chengdu BOE Optoelectronics Technology Co., Ltd., Chengdu (CN)

(72) Inventors: Haigang QING, Beijing (CN); Xiaojing QI, Beijing (CN)

(21) Appl. No.: 14/548,970

(22) Filed: Nov. 20, 2014

(30) Foreign Application Priority Data
Jun. 17, 2014 (CN) 201410270425.4

(51) Int. Cl. H03K 17/30; H03K 17/567; G09G 3/36; G11C 19/18

(52) U.S. Cl. CPC H03K 17/302; G11C 19/184; H03K 17/567; G09G 3/3648; G09G 2310/0286; G09G 2300/0814; G09G 2320/045

(57) ABSTRACT

Provided is a dual pull-down control module including a signal input terminal, a pull-down signal output terminal, and a clock input terminal. The dual pull-down control module further includes: a control subunit, of which a first terminal is connected to the signal input terminal; a fifth thin film transistor, of which a gate is connected to a second terminal of the control subunit, a first pole is connected to a third terminal of the control subunit, and a second pole is connected to the clock input terminal; and a unidirectional turn-on element, of which a first terminal is connected to the third terminal of the control subunit, a second terminal is connected to the second pole of the fifth thin film transistor. The unidirectional turn-on element is turned on when a level at the first terminal thereof is higher than a level at the second terminal thereof.

### FIELD OF THE INVENTION

The present invention relates to driving of a display panel, particularly, relates to a dual pull-down control module, a shift register unit including the dual pull-down control module, a gate driver including the shift register unit, and a display panel including the gate driver.

### BACKGROUND OF THE INVENTION

In a TFT-LCD (Thin Film Transistor Liquid Crystal Display), the detailed steps of displaying a frame are as follows: the data signals, which are required for each row of pixels, are outputted in sequence from top to down by a source driver, and then a gate driver sequentially inputs a square wave with a certain width to the gates of in each row of pixels from top to down for gating.

A plurality of integrated gate driving circuits are intended to obtain a characteristic of alternating pull-down so as to overcome the floating of an output of the circuit and the drift of the characteristics of a TFT. However, in a dual-clock circuit, the alternating pull-down solution causes a problem that an output pull-up clock discharges to a dual pull-down node with a large current during an outputting process. The dual pull-down node is open to a low level signal, and a pull-up transistor is turned on for the dual pull-down node, so a high level clock directly discharges to the low level. This results in that the dual pull-down node cannot be pulled down to the desired low level which is used to turn off the pull-down transistor, hence, a leakage current at an output terminal increases. Meanwhile, since the pull-up clock directly discharges to the low level, the load of a power supply significantly increases and hence the power consumption significantly increases.

As discussed above, an urgent technical problem to be solved in the art is how to reduce the power consumption of the display panel.

### SUMMARY OF THE INVENTION

The object of the present invention is to provide a dual pull-down control module, a shift register unit including the dual pull-down control module, a gate driver including the shift register unit, and a display panel including the gate driver. The display panel has a low power consumption.

To achieve the above object, an aspect of the present invention provides a dual pull-down control module including a signal input terminal, a pull-down signal output terminal, and a clock input terminal, wherein the dual pull-down control module further includes:

a control subunit, a first terminal of the control subunit is connected to the signal input terminal, a second terminal and a third terminal of the control subunit are at low level signal when the signal input terminal is at high level signal;

a fifth thin film transistor, a gate of the fifth thin film transistor is connected to the second terminal of the control subunit, a first pole of the fifth thin film transistor is connected to the third terminal of the control subunit, a second pole of the fifth thin film transistor is connected to the clock input terminal; and

a unidirectional turn-on element, a first terminal of the unidirectional turn-on element is connected to the third terminal of the control subunit, a second terminal of the unidirectional turn-on element is connected to the second pole of the fifth thin film transistor, the unidirectional turn-on element is turned on when a level at the first terminal of the unidirectional turn-on element is higher than a level at the second terminal of the unidirectional turn-on element.

Preferably, the control subunit includes:

a low level input terminal;

a sixth thin film transistor, a gate of the sixth thin film transistor is connected to the first terminal of the control subunit, a first pole of the sixth thin film transistor is connected to the low level input terminal, a second pole of the sixth thin film transistor is connected to the third terminal of the control subunit; and

a seventh thin film transistor, a gate of the seventh thin film transistor is connected to the first terminal of the control subunit, a first pole of the seventh thin film transistor is connected to the low level input terminal, a second pole of the seventh thin film transistor is connected to the second terminal of the control subunit.

Preferably, the unidirectional turn-on element is a thin film transistor, a second pole of the unidirectional turn-on element is connected to the second pole of fifth thin film transistor, a gate and a first pole of the unidirectional turn-on element are connected to the pull-down signal output terminal; or

the unidirectional turn-on element is a diode, an anode of the diode is used as the first terminal of the unidirectional turn-on element and a cathode of the diode is used as the second terminal of the unidirectional turn-on element.

Preferably, the dual pull-down control module further includes a first capacitor, wherein, a first terminal of the first capacitor is connected to the second pole of the fifth thin film transistor, and a second terminal of the first capacitor is connected to the gate of the fifth thin film transistor.

Another aspect of the present invention provides a shift register unit including:

a pull-up module;

a charging and resetting module, which includes a scan input terminal and a reset terminal, the scan input terminal inputs a high level signal for charging the pull-up module during a pre-charging stage of the shift register unit, the reset terminal inputs a high level signal for discharging the pull-up module during a discharging stage of the shift register unit;

a first clock input terminal, which is used for proving a first clock signal to the shift register unit;

a dual pull-down control module according to the present invention;

an output pull-down module, which is used for pulling down a level at an output terminal of the shift register unit to a low level during stages after the output terminal of the shift register unit outputs a high level signal; and

a dual pull-down module;

wherein, the signal input terminal of the dual pull-down control module is connected to the output terminal of the charging and resetting module, and the signal input terminal of the dual pull-down control module is connected to a pull-up node of the pull-up module, the pull-down signal output terminal of the dual pull-down control module is connected to a pull-down node of the dual pull-down module, and the clock input terminal of the dual pull-down control module is connected to the first clock input terminal.

Preferably, the charging and resetting module includes a ninth thin film transistor, a tenth thin film transistor, a first reference voltage input terminal, and a second reference voltage input terminal, wherein:

a gate of the ninth thin film transistor is connected to the scan input terminal, a first pole of the ninth thin film transistor is connected to the first reference voltage input terminal, and a second pole of the ninth thin film transistor is connected to a first pole of the tenth thin film transistor;

a gate of the tenth thin film transistor is connected to the reset terminal, a second pole of the tenth thin film transistor is connected to the second reference voltage input terminal; and

one of the first reference voltage input terminal and the second reference voltage input terminal is a high level signal input terminal, and another one of the first reference voltage input terminal and the second reference voltage input terminal is a low level signal input terminal.

Preferably, the output pull-down module includes a second clock input terminal and a third thin film transistor, wherein:

a gate of the third thin film transistor is connected to the second clock input terminal;

a first pole of the third thin film transistor is connected to the output terminal of the shift register unit; and

a second pole of the third thin film transistor is connected to a low level input terminal of the dual pull-down module.

Preferably, the dual pull-down module includes a low level input terminal, a second thin film transistor, and a eighth thin film transistor, wherein:

a gate of the second thin film transistor and a gate of the eighth thin film transistor are both connected to the pull-down node; a first pole of the second thin film transistor is connected to the output terminal of the shift register unit; a second pole of the second thin film transistor is connected to the low level input terminal; and

a first pole of the eighth thin film is connected to the pull-up node; and a second pole of the eighth thin film is connected to the low level input terminal.

Preferably, the pull-up module includes a first thin film transistor and a second capacitor, wherein:

a gate of the first thin film transistor is connected to the pull-up node; a first pole of the first thin film transistor is connected to the first clock input terminal; a second pole of the first thin film transistor is connected to the output terminal of the shift register unit; and

a first terminal of the second capacitor is connected to the pull-up node, and a second terminal of the second capacitor is connected to the output terminal of the shift register unit.

Still another aspect of the present invention provides a gate driver, including a plurality of cascaded shift register units according to the present invention, wherein:

the scan input terminal of the shift register unit is connected to an output terminal of a shift register unit in a previous stage, and the reset terminal of the shift register unit is connected to an output terminal of a shift register unit in a next stage.

Still another aspect of the present invention provides a display device including the gate driver according to the present invention.

In a pull-up stage of the shift register unit according to the present invention, a signal input into the control subunit from the signal input terminal is a high level at the pull-up node. Thus, the second terminal and the third terminal of the control subunit are still at a low level. In this stage, the fifth thin film transistor and the unidirectional turn-on element are still turned off. Therefore, the first clock input terminal, which is connected to the clock input terminal, will not discharge to the pull-down node, hence an energy consumption of the shift register unit is reduced.

In the shift register unit according to the present invention, an alternating pull-up can be applied to the output terminal by the dual pull-down control module and the output pull-down module, thus, a floating effect and a stray effect of signals output from the output terminal are overcome effectively.

### BRIEF DESCRIPTION OF THE DRAWINGS

The drawings are for the purpose of providing better understanding of the present invention and are a part of the description. The drawings are used for describing the present invention together with the specific embodiments as follows, but are not intended to limit the present invention. Wherein:

FIG. 1 is a circuit diagram of the shift register unit according to the present invention;

FIG. 2 is a timing sequence diagram of signals in the shift register unit shown in FIG. 1; and

FIG. 3 is a schematic diagram of the gate driver according to the present invention.

### REFERENCE NUMERALS

10: charging and resetting module;
20: dual pull-down control module;
21: control subunit;
30: dual pull-down module;
40: pull-up module;
50: output pull-down module;
T1: first thin film transistor (TFT);
T2: second thin film transistor (TFT);
T3: third thin film transistor (TFT);
T4: unidirectional turn-on element;
T5: fifth thin film transistor (TFT);
T6: sixth thin film transistor (TFT);
T7: seventh thin film transistor (TFT);
T8: eighth thin film transistor (TFT);
T9: ninth thin film transistor (TFT);
T10: tenth thin film transistor (TFT);
C1: first capacitor;
C2: second capacitor; and
Reset: reset terminal.

### DETAILED DESCRIPTION OF THE EMBODIMENTS

Embodiments of the present invention will be described in more details in conjunction with the accompanying drawings. It should be understood that, the embodiments described herein are merely used for illustrating and explaining the present invention, but not intended to limit the scope of the present invention.

It should be understood that the term of “a first pole” represents one of the source and the drain of a TFT, and the term of “a second pole” represents the other one of the source and the drain of the TFT.

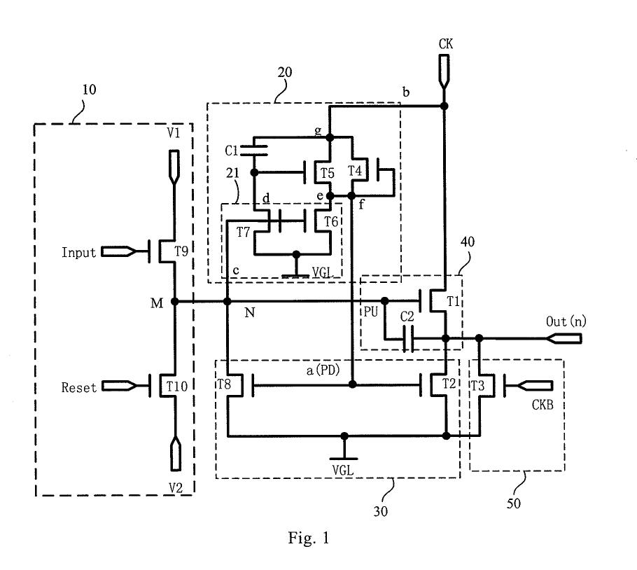

FIG. 1 is a circuit diagram of the shift register unit according to the present invention. As shown in FIG. 1, according to one aspect of the present invention, a dual pull-down control module 20 includes a signal input terminal N, a pull-down signal output terminal a, and a clock input terminal b. The dual pull-down control module 20 further includes:

a control subunit 21, a first terminal c of the control subunit 21 is connected to the signal input terminal N, a second terminal d and a third terminal e of the control subunit 21 is at low level VGL when the signal input terminal N is at high level; a fifth TFT T5, the gate of the fifth TFT T5 is connected to the second terminal d of the control subunit 21, a first pole of the fifth TFT T5 is connected to the third terminal e of the control subunit 21, a second pole of fifth TFT T5 is connected to the clock input terminal b; and a unidirectional turn-on element T4, a first terminal f the of the unidirectional turn-on element T4 is connected to the third terminal e of the control subunit 21, a second terminal g of the unidirectional turn-on element T4 is connected to the second pole of the fifth TFT T5, the unidirectional turn-on element T4 is turned on when the level at the first terminal f of the unidirectional turn-on element T4 is higher than the level at the second terminal g of the unidirectional turn-on element T4.

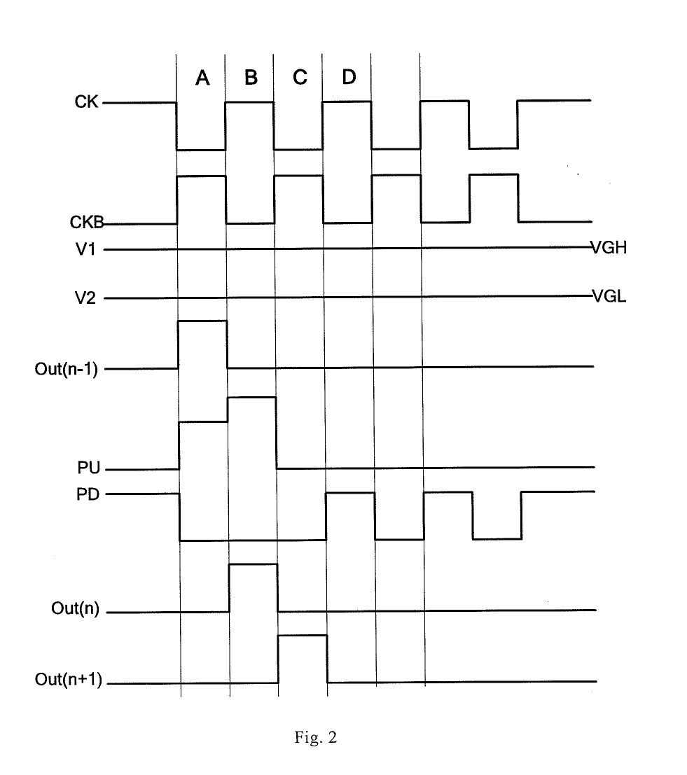

FIG. 2 is a timing sequence diagram of signals in the shift register unit shown in FIG. 1. As shown in FIGS. 1 and 2, the dual pull-down control module 20 is applied in the shift register unit. During a pull-up stage of the shift register unit (Stage B in the FIG. 2), the signal output from the signal input terminal N to the control subunit 21 is the high level VGH at a pull-up node PU. So the second terminal d and the third terminal e of the control subunit 21 is at the low level VGL. In this stage, the fifth TFT T5 and the unidirectional turn-on element T4 are both turned off, so that the first clock input terminal CK, which is connected to the clock input terminal b, will not discharge to a pull-down node PD, and hence the energy consumption of the shift register unit can be reduced.

Hereinafter, the specific working status of the dual pull-down control module 20 in each stage of the shift register unit will be described in detail.

In the present invention, the specific structure of the control subunit 21 is not particularly limited, as long as the second terminal d and the third terminal e of the control subunit 21 are both at a low level in the pull-up stage (Stage B in FIG. 2) of the shift register unit. Specifically, as a preferable embodiment of the present invention, as shown in FIG. 1, the control subunit 21 may further include a low level input terminal, a sixth TFT T6 and a seventh TFT T7. The gate of the sixth TFT T6 and the gate of the seventh TFT T7 are both connected to the first terminal c of the control subunit 21, a first pole of the sixth TFT T6 is connected to the low level input terminal, a second pole of the sixth TFT T6 is connected to the third terminal e of the control subunit 21, a first pole of the seventh TFT T7 is connected to the low level input terminal, a second pole of the seventh TFT T7 is connected to the second terminal d of the control subunit 21.

The sixth TFT T6 and the seventh TFT T7 are turned on when the signal input terminal N of the dual pull-down control module 20 is at high level, so that the level at the second terminal d and the third terminal e of the control subunit 21 are both pulled down to the low level VGL.

In the present invention, the specific structure of unidirectional turn-on element is also not particularly limited, as long as the unidirectional turn-on element T4 is turned off when the level at the second terminal g of the unidirectional turn-on element T4 is higher than that at the first terminal f of the unidirectional turn-on element T4. For example, the unidirectional turn-on element T4 may be a diode. The anode of the diode may be used as the first terminal of the unidirectional turn-on element T4 and the cathode of the diode may be used as the second terminal of the unidirectional turn-on element T4.

As a preferable embodiment of the present, as shown in FIG. 1, the unidirectional turn-on element T4 may be a TFT, a second pole of the unidirectional turn-on element T4 is connected to the second pole of the fifth TFT T5, the gate of the unidirectional turn-on element T4 and a first pole of the unidirectional turn-on element T4 are both connected to the pull-down signal output terminal a (i.e., the gate of the unidirectional turn-on element T4 is connected to the first pole of the unidirectional turn-on element T4). The unidirectional turn-on element T4 is turned off when the clock input terminal b input a signal at high level VGH to the second pole of the unidirectional turn-on element T4 and the third terminal of the control subunit 21 is at a low level. It should be understand that, here, the second pole of the unidirectional turn-on element T4 is the above-described second terminal g of the unidirectional turn-on element T4, and the first pole of the unidirectional turn-on element T4 and the gate of the unidirectional turn-on element T4, which are connected with each other, are the above-described first terminal f of the unidirectional turn-on element T4.

In order to ensure that the fifth TFT is turned on during a low level maintaining stage (i.e., the Stage D in the FIG. 2) of the shift register unit, so as to completely turn off the first TFT T1 in the shift register unit as shown in FIG. 1. Preferably, in the low level maintaining stage, the fifth TFT T5 is turned on, so as to input a high-level first clock signal, which is output from the first clock input terminal CK, to the pull-down node PD, so that the second TFT T2 and the eighth TFT T8 in the dual pull-down module 30 of the shift register unit (as shown in FIG. 1) are turned on, and the level at the pull-up node PU is pulled down to the low level VGL, and hence the first TFT T1 in a pull-up module 40 is completely turned off.

In the present invention, turning on the fifth TFT T5 during the low level maintaining stage of the shift register unit can be realized by various means. For example, an external signal source can be introduced for providing signals to the gate of the fifth TFT T5, so as to turn on the fifth TFT T5 during the low level maintaining stage of shift register unit.

In order to simplify the structure of the shift register unit including the dual pull-down control module 20, preferably, the dual pull-down control module 20 may further include a first capacitor C1, a first terminal of the first capacitor C1 is connected to the second pole of the fifth TFT T5, a second terminal of the first capacitor C1 is connected to the gate of the fifth TFT T5. During the low level maintaining stage of the shift register unit, the first clock input terminal CK inputs the high level VGH signal to the clock input terminal b of the dual pull-down control module 20, so that the level at the gate of the fifth TFT T5 is pulled up to a high level by the coupling of the first capacitor C1, hence the fifth TFT T5 is turned on. The high level signal output from the first input terminal CK is input to the pull-down node PD via the fifth TFT T5 and pulls the level at the pull-down node PD up to the high level, so that the second TFT T2 and the eighth TFT T8 (as shown in FIG. 1) are turned on and the level at pull-up node PU is pulled down to the low level VGL by the eighth TFT T8, so as to turn off the first TFT T1 and hence to make sure that the output terminal Out(n) of the shift register unit can be at the low level.

As another aspect of the present invention, as shown in FIG. 1, provides a shift register unit including the following components:

A pull-up module 40, the specific structure of the pull-up module 40 is not particularly limited in the present invention. As shown in FIG. 1, as an embodiment of the present invention, the pull-up module 40 may include a first thin film transistor (TFT) T1 and a second capacitor C2. The gate of the first TFT T1 is connected to the pull-up node PU, and a first pole of the first TFT T1 is connected to the first clock input terminal CK, a second pole of the first TFT T1 is connected to the output terminal Out(n) of the shift register unit. A first terminal of the second capacitor C2 is connected to the pull-up node PU, and a second terminal of the second capacitor C2 is connected to the output terminal Out(n) of the shift register unit;

A charging and resetting module 10, including a scan input terminal Input and a resetting terminal Reset. During a pre-charging stage of the shift register unit, the scan input terminal Input inputs a high level signal to charge the pull-up module 40. During a discharging stage of the shift register unit, the resetting terminal Reset inputs a high level signal to discharge the pull-up module 40;

A first clock input terminal CK, which is used for providing a first clock signal to the shift register unit;

A dual pull-down control module 20 as described above. Further, the signal input terminal N of the dual pull-down control module 20 is connected to a signal output terminal M of the charging and resetting module 10, and the signal input terminal N of the dual pull-down control module 20 is connected to the pull-up node PU of the pull-up module 40, the pull-down signal output terminal a of the dual pull-down control module 20 is connected to the pull-down node PD of the dual pull-down module 30, the clock input terminal b of the dual pull-down control module 20 is connected to the first clock input terminal CK.

An output pull-down module 50, which is used for pulling down the level at the output terminal of the shift register unit to a low level during the stages (including the pull-down Stage C in FIG. 2) after the output terminal of the shift register unit outputs a high level signal; and

A dual pull-down module 30, the specific structure of the dual pull-down module 30 is not particularly limited in the present invention either. As shown in FIG. 1, the dual pull-down module 30 may include a eighth TFT T8, a second TFT T2, and a low level input terminal which can provide a low level signal VGL. The low level input terminal of the dual pull-down module 30 may be the same as the low level input terminal of the control subunit 21. The gate of the eighth TFT T8 is connected to the pull-down node PD, a first pole of the eighth TFT T8 is connected to the signal input terminal N of the dual pull-down control module 20, a second pole of the eighth TFT T8 is connected to the low level input terminal of the dual pull-down module 30. The gate of the second TFT T2 is connected to the pull-down node PD, a first pole of the second TFT T2 is connected to the output terminal Out(n) of the shift register unit, and a second pole of the second TFT T2 is connected to the low level input terminal of the dual pull-down module 30.

In the prior art, there are various setting mode of the pull-up module 40 and the dual pull-down module 30, so the details will not be described here.

Hereinafter the specific working status of the shift register unit in each stage will be described in detail.

In the pre-charging stage of the shift register unit (the Stage A in FIG. 2), the signal input to the signal input terminal N is the high level VGH which is input from the charging and resetting module 10. Therefore, the gate voltages of the sixth TFT T6 and the seventh TFT T7 are high levels, so that the sixth TFT T6 and the seventh TFT T7 are turned on. The second terminal d and the third terminal e of the control subunit 21 is at the low level VGL. The gate voltages of the fifth TFT T5 and the unidirectional turn-on element T4 are the low level VGL. Thus, in this stage, the fifth TFT T5 and the unidirectional turn-on element T4 are both turned off. As a result, an electric potential at the pull-down node PD, which is connected to the pull-down signal output terminal a of the dual pull-down control module 20, is the low level VGL at the third terminal e of the dual pull-down control module 20.

As described above, during the pull-up stage (Stage B in FIG. 2) of the shift register unit, the level of a signal output from the signal input terminal N to the control subunit 21 is the high level VGH at the pull-up node PU. Therefore, the second terminal d and the third terminal e of the control subunit 21 are still at the low level VGL. In this stage, the fifth TFT and the unidirectional turn-on element T4 are still both turned off. As a result, the first clock input terminal CK, which is connected with the clock input terminal b, will not discharge to the pull-down node PD, so as to reduce the energy consumption of the shift register unit.

In the pull-down stage (Stage C in FIG. 2) of the shift register unit, the level at the pull-up node PU is pulled down to the low level, the level at the shift register unit is the low level at the output pull-down module 50. The main function of the output pull-down module 50 is providing the low level signal to the output terminal of the shift register unit during the pull-down stage of the shift register unit.

During the low level maintaining stage (Stage D in FIG. 2) of the shift register unit, the signal which is output from the signal terminal N to the control subunit 21 is a low level signal. The sixth TFT T6 and the seventh TFT T7 are both turned off, the fifth TFT T5 is turned on, and the level at the pull-down node PD is pulled up by the high level input from the first clock input terminal CK, so as to turn on the second TFT T2 and the eighth TFT T8. The level at the pull-up node PU is pulled down to the low level VGL, so as to turn off the first TFT T1 of the pull-up module 40, and hence ensure that the level at the output terminal Out(n) can be pulled down to the low level VGL by the second TFT T2 of the dual pull-down module 30.

As a specific implementation of the present invention, as shown in FIG. 1, the charging and resetting module 10 may include a ninth TFT T9, a tenth TFT T10, a first reference voltage input terminal V1, a second reference voltage input terminal V2, scan input terminal Input, and a reset terminal Reset. The gate of the ninth TFT T9 is connected to the input terminal Input, a first pole of the ninth TFT T9 is connected to the first reference voltage input terminal V1, a second pole of the ninth TFT T9 is connected to a first pole of the tenth TFT T10, the gate of the tenth TFT T10 is connected to the reset terminal Reset, a second pole of the tenth TFT T10 is connected to the second reference voltage input terminal V2, one of the first reference voltage input terminal V1 and the second reference voltage input terminal V2 is a high level input terminal, and the other one is a low level input terminal. The high level input terminal can provide the high level VGH signal, and the low level input terminal can provide the low level VGL signal.

It can be easily understood that a gate driver includes a plurality of cascaded shift register units. When the shift register units according to the present invention are provided in the gate driver, the scan input terminal Input is connected to the output terminal of the shift register unit in the previous stage, and the reset terminal Reset is connected to the output terminal of the shift register unit in the next stage. When a forward scan is performed on a display panel including the above-mentioned gate driver, the first reference voltage input terminal V1 is a high level signal input terminal and the second reference voltage input terminal V2 is a low level signal input terminal; and when a reverse scan is performed on the display panel including the above-mentioned gate driver, the first reference voltage input terminal V1 is a low level signal input terminal and the second reference voltage input terminal V2 is a high level signal input terminal.

As a preferred embodiment of the present invention, the output pull-down module 50 includes a second clock input terminal CKB and a third TFT T3. The gate of the third TFT T3 is connected to the second clock input terminal CKB, a first pole of the third TFT T3 is connected to the output terminal Out(n) of the shift register unit, and a second pole of the third TFT T3 is connected to the low level input terminal. The advantage of this structure of the output pull-down module 50 is that alternating pull-down the level at the output terminal of the shift register unit can be realized.

As shown in FIG. 2, a timing sequence of a first clock signal input from the first clock input terminal CK and a timing sequence of a second clock signal input from the second clock input terminal CKB are complementary. That is, when the first clock input terminal CK is at high level, the second clock input terminal CKB is at low level, and when the first clock input terminal CK is at low level, the second clock input terminal CKB is at high level. After the second clock input terminal CKB is at a high level, the third TFT T3 is turned on, and the electric potential at the output terminal Out(n) of the shift register unit is pulled down to low level VGL. In the stages after the output terminal Out(n) of the shift register is at high level (i.e., the stages after the Stage B, including the Stage C and Stage D in FIG. 2), the first clock input terminal CK and the second clock input terminal CKB alternatively control the output terminal of the shift register unit to output a low level signal(i.e., realizing the alternating pull-down the level at the output terminal of the shift register unit).

Particularly, during the pull-down stage (i.e., the Stage C in FIG. 2) of the shift register unit, the second clock input terminal CKB inputs a high level signal, the third TFT T3 is turned on, so as to pull down the electric potential at the Out(n) to a low level. During the low level maintaining stage (i.e., the Stage D in FIG. 2) of the shift register unit, the fifth TFT T5 is turned on, the level at the pull-down node PD is pulled up by the high level signal input from the first clock input terminal CK, the second TFT T2 and the eighth TFT T8 of the dual pull-down module 30 are turned on, the level at the pull-up node is pulled down to the low level VGL, so as to turn off the first TFT T1 in the pull-up module 40. Thus, the level at the output terminal Out(n) can be pulled down to the low level VGL by the second TFT T2 of the dual pull-down module 30.

As a specific implementation of the present invention, as shown in FIG. 1, the dual pull-down module 30 may include the second TFT T2 and the eighth TFT T8, the gate of the second TFT T2 and the gate of the eighth TFT T8 are both connected to the pull-down node PD. The first pole of the second TFT T2 is connected to the output terminal Out(n) of the shift register unit, and the second pole of the second TFT T2 is connected to the low level input terminal of the dual pull-down module 30. The first pole of the eighth TFT T8 is connected to the pull-up node PU, and the second pole of the eighth TFT T8 is connected to the low level input terminal of the dual pull-down module 30.

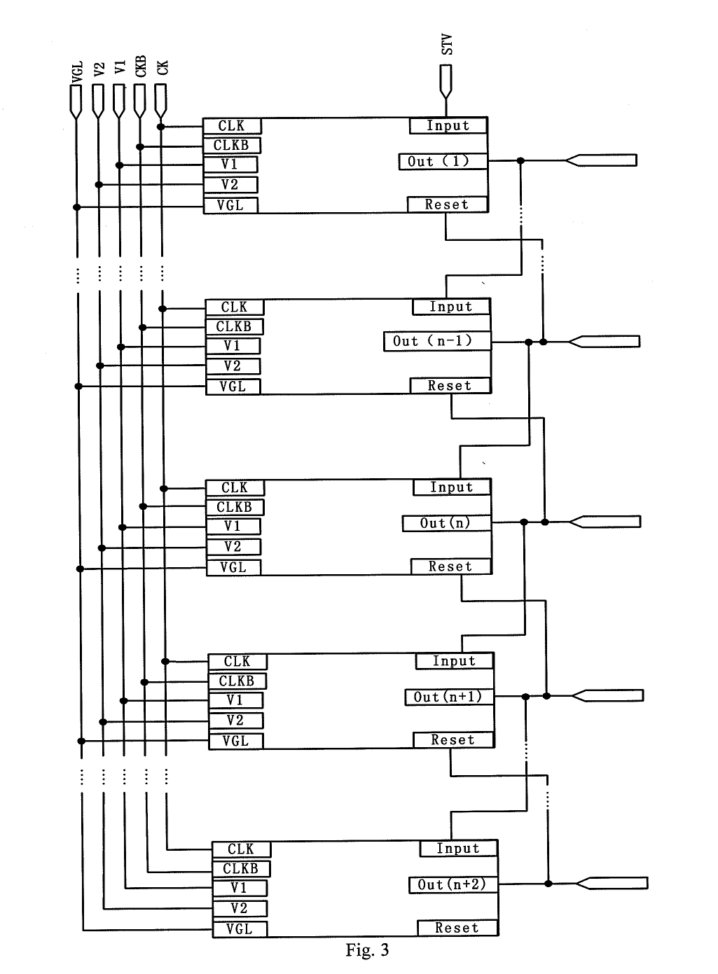

As still another aspect of the present invention, as shown in FIG. 3, there is provided a gate driver including a plurality of cascaded shift register units. Wherein each of the shift register units is the above shift register unit provided by the present invention, the scan input terminal Input is connected to the output terminal of the shift register unit in the previous stage, and the reset terminal Reset is connected to the output terminal of the shift register unit in the next stage.

If n>1, the scan input terminal Input of the charging and resetting module 10 of the shift register unit in stage n receives the output signal Out(n−1) of the shift register unit in stage n−1, and the reset terminal Reset of the charging and resetting module 10 of the shift register unit in stage n receives the output signal Out(n+1) of the shift register unit in stage n+1. The pull-up stage (i.e., the Stage B in FIG. 2) of the shift register unit in stage n−1 corresponds to the pre-charging stage of the shift register unit in stage n, and the pull-up stage of the shift register unit in stage n+1 corresponds to the pull-down stage of the shift register unit in stage n. Further, FIG. 3 also shows a shift register unit in stage n+2, the output signal of the shift register unit in stage n+2 is Out(n+2).

If n=1, the scan input terminal Input of the charging and resetting module 10 of the shift register unit in stage n receives a STV signal. Those skilled in the art should understand that the STV signal is at high level only during the pre-charging stage (i.e., the Stage A in FIG. 2) of the shift register unit in stage 1, and is at low level during the other stages.

Hereinafter, the specific working process of the gate driver comprising the shift register unit according to the present invention will be described in detail in conjunction with FIG. 1 to FIG. 3. In the present embodiment, the gate driver comprising the shift register unit performs a forward scan on a display panel, the first reference voltage input terminal V1 inputs the high level VGH signal, and the second reference voltage input terminal V2 inputs the low level VGL signal.

During the stage A of FIG. 2, the first clock input terminal CK inputs a first clock signal at low level, and the second clock input terminal CKB inputs a second clock signal at high level. The input terminal of the charging and resetting module 10 of the shift register unit in stage n receives the output signal Out(n−1), which is at high level VGH, of the shift register unit in stage n−1, and the reset terminal Reset of the charging and resetting module 10 of the shift register unit in stage n receives the output signal Out(n+1), which is at low level VGL at this time, of the shift register unit in stage n+1. In Stage A, the gate of the ninth TFT T9 of the charging and resetting module 10 is at the high level VGH, so the ninth TFT T9 is turned on. Thus, the levels at the signal input terminal N of the dual pull-down control module 20 and the pull-up node PU of the pull-up module 40 are both the high level VGH at the first reference voltage input terminal V1, and the second capacitor C2 is charged by the pull-up node PU. The sixth TFT T6 and the seventh TFT T7 are turned on since the level at the signal input terminal N of the dual pull-down control module 20 is a high level, so that the second terminal d and the third terminal e of the control subunit 21 are both at the low level VGL. Therefore, the fifth TFT T5 is turned off, the electric potential at the pull-down node PD of the dual pull-down module 30 is pulled down to the low level VGL by the sixth TFT T6. The unidirectional turn-on element T4 is turned off since the first clock signal input from the first clock input terminal CK is at low level. The gate of the first TFT T1 is the pull-up node PU, so the first TFT T1 is turned on. The second clock signal input from the second clock input terminal CKB is at high level, so the third TFT T3 is turned on, and hence the electric potential at the output terminal Out(n) of shift register unit in stage n is pulled down to the low level VGL.

During the Stage B in FIG. 2, the electric potential of the scan input terminal Input of the charging and resetting module 10 changes to low level, and the electric potential of the reset terminal Reset of the charging and resetting module 10 remains at low level, so the ninth TFT T9 and the tenth TFT T10 are both turned off. The first clock signal input from the first clock input terminal CK is at the high level VGH. There is no discharging path for the pull-up node PU, so the pull-up node PU and the signal input terminal N of the dual pull-down control module 20 remain at high level, so that the first TFT T1, the sixth TFT T6, and the seventh TFT T7 remain turning on. The second terminal D of the control subunit 21 is at low level, so the fifth TFT T5 is still turned off, and the pull-down node PD still remains at the low level VGL. Therefore, the second TFT T2 and the eighth TFT T8 is turned off. The first clock signal input from the first clock input terminal CK can not enter the pull-down node PD through the fifth TFT T5 since the fifth TFT T5 is turned off. And the first clock signal input from the first clock input terminal CK can not discharge to the pull-down node PD through the unidirectional turn-on element T4 since the unidirectional turn-on element T4 is turned off at this time. So the problem of a high power consumption of the gate driver can be avoided. Since the first clock signal input from the first clock input terminal CK is at the high level VGH, the first TFT T1 is turned on, and the third TFT T3 is turned off, the signal output from the output terminal Out(n) of shift register unit in the present stage is the high level signal input from the first clock input terminal CK.

During the Stage C in FIG. 2, the first clock signal input from the first clock input terminal CK is at low level, the second clock signal input from the second clock terminal CKB is at high level, the electric potential at scan input terminal Input of the charging an resetting module 10 remains at low level, and the electric potential at reset terminal Reset of the charging an resetting module 10 changes to the high level. Thus, the ninth TFT T9 is turned off, the tenth TFT T10 is turned on, and the electric potential at the pull-up node PU is pulled down to the low level VGL by the tenth TFT T10. The resetting process of the circuit is accomplished by the above actions. As a result, the first TFT T1, the sixth TFT T6, and the seventh TFT T7 are turned off, the pull-down node PD remains at low level, the second TFT T2 and the eighth TFT T8 are still turned off. The second clock signal input from the second clock input terminal CKB is at high level, so the third TFT T3 is turned on, and the electric potential at the output terminal Out(n) of the shift register unit in stage n is pulled down to the low level VGL.

During the Stage D in FIG. 2, the first clock signal input from the first clock input terminal CK is at high level, the second clock signal input from the second clock terminal CKB is at low level, the electric potential at scan input terminal Input of the charging an resetting module 10 remains at low level, and the electric potential at the reset terminal Reset of the charging an resetting module 10 changes to low level. Since the first clock signal input from the first clock input terminal CK is at high level, so the gate of the fifth TFT T5 is coupled to be at high level by the first capacitor C1. So the fifth TFT T5 is turned on. In this case, the level at the pull-down node PD is pulled up to high level by the first clock signal. The second TFT T2 and the eighth TFT T8 are turned on, the level at the pull-up node PU is further pulled down to the low level VGL by the eighth TFT T8. So the first TFT T1 is turned off well and hence level at the output terminal Out(n) is pulled down to the low level VGL by the second TFT T2. It can be seen that an alternating pull-up can be applied to the output terminal by the dual pull-down control module 20 and dual pull-down module 30, so as to overcome a floating effect and a stray effect of signals output from the output terminal.

As still another aspect of the present invention, there is provided a display panel including the gate driver according to the present invention.

Those skilled in the art should understand that a shift register unit in each stage correspond to one gate line of the display panel. That is, an output terminal of a shift register unit in each stage is connected to one gate line for providing a scanning signal to the corresponding gate line.

Since the above-mentioned display panel according to the present invention adopts the gate driver according to the present invention, the energy consumption of the display panel according to the present invention is low. Moreover, the level at the output terminal is reliably pulled down to a low level during the low level maintaining stage of the shift register unit. Thus, the floating effect and the stray effect of signals output from the output terminal are avoided in the display panel according to the present invention.

The display panel provided by the present invention can be used in display devices such as a cell phone, a computer display device, a tablet computer, and the like.

It should be understood that, the above embodiments are only exemplary embodiments for the purpose of explaining the principle of the present invention, and the present invention is not limited thereto. For a person skilled in the art, various improvements and modifications may be made to the present invention without departing from the spirit and essence of the present invention. These improvements and modifications also fall within the protection scope of the present invention.

What is claimed is:

1. A dual pull-down control module, including a signal input terminal, a pull-down signal output terminal, and a clock input terminal, wherein the dual pull-down control module further includes:
a control subunit, a first terminal of the control subunit is connected to the signal input terminal, a second terminal and a third terminal of the control subunit are at low level when the signal input terminal is at high level;
a fifth thin film transistor, a gate of the fifth thin film transistor is connected to the second terminal of the control subunit, a first pole of the fifth thin film transistor is connected to the third terminal of the control subunit, a second pole of the fifth thin film transistor is connected to the clock input terminal; and
a unidirectional turn-on element, a first terminal of the unidirectional turn-on element is connected to the third terminal of the control subunit, a second terminal of the unidirectional turn-on element is connected to the second pole of the fifth thin film transistor, the unidirectional turn-on element is turned on when a level at the first terminal of the unidirectional turn-on element is higher than a level at the second terminal of the unidirectional turn-on element.

2. The dual pull-down control module according to claim 1, wherein the control subunit includes:
a low level input terminal;
a sixth thin film transistor, a gate of the sixth thin film transistor is connected to the first terminal of the control subunit, a first pole of the sixth thin film transistor is connected to the low level input terminal, a second pole of the sixth thin film transistor is connected to the third terminal of the control subunit; and
a seventh thin film transistor, a gate of the seventh thin film transistor is connected to the first terminal of the control subunit, a first pole of the seventh thin film transistor is connected to the low level input terminal, a second pole of the seventh thin film transistor is connected to the second terminal of the control subunit.

3. The dual pull-down control module according to claim 1, wherein, the unidirectional turn-on element is a thin film transistor, a second pole of the unidirectional turn-on element is connected to the second pole of fifth thin film transistor, a gate and a first pole of the unidirectional turn-on element are connected to the pull-down signal output terminal; or
the unidirectional turn-on element is a diode, an anode of the diode is used as the first terminal of the unidirectional turn-on element and a cathode of the diode is used as the second terminal of the unidirectional turn-on element.

4. The dual pull-down control module according to claim 1, further including a first capacitor, wherein, a first terminal of the first capacitor is connected to the second pole of the fifth thin film transistor, and a second terminal of the first capacitor is connected to the gate of the fifth thin film transistor.

5. The dual pull-down control module according to claim 2, further including a first capacitor, wherein, a first terminal of the first capacitor is connected to the second pole of the fifth thin film transistor, and a second terminal of the first capacitor is connected to the gate of the fifth thin film transistor.

6. The dual pull-down control module according to claim 3, further including a first capacitor, wherein, a first terminal of the first capacitor is connected to the second pole of the fifth thin film transistor, and a second terminal of the first capacitor is connected to the gate of the fifth thin film transistor.

7. A shift register unit, including:
a pull-up module;
a charging and resetting module, which includes a scan input terminal and a reset terminal, the scan input terminal inputs a high level signal for charging the pull-up module during a pre-charging stage of the shift register unit, the reset terminal inputs a high level signal for discharging the pull-up module during a discharging stage of the shift register unit;
a first clock input terminal, which is used for proving a first clock signal to the shift register unit;
a dual pull-down control module, which includes a signal input terminal, a pull-down signal output terminal, and a clock input terminal, the dual pull-down control module further includes:
a control subunit, a first terminal of the control subunit is connected to the signal input terminal, a second terminal and a third terminal of the control subunit are at low level signal when the signal input terminal is at high level;
a fifth thin film transistor, a gate of the fifth thin film transistor is connected to the second terminal of the control subunit, a first pole of the fifth thin film transistor is connected to the third terminal of the control subunit, a second pole of the fifth thin film transistor is connected to the clock input terminal; and
a unidirectional turn-on element, a first terminal of the unidirectional turn-on element is connected to the third terminal of the control subunit, a second terminal of the unidirectional turn-on element is connected to the second pole of the fifth thin film transistor, the unidirectional turn-on element is turned on when a level at the first terminal of the unidirectional turn-on element is higher than a level at the second terminal of the unidirectional turn-on element;
an output pull-down module, which is used for pulling down a level at an output terminal of the shift register unit to a low level during stages after the output terminal of the shift register unit outputs a high level signal; and
a dual pull-down module;
wherein, the signal input terminal of the dual pull-down control module is connected to the output terminal of the charging and resetting module, and the signal input terminal of the dual pull-down control module is connected to a pull-up node of the pull-up module, the pull-down signal output terminal of the dual pull-down control module is connected to a pull-down node of the dual pull-down module, and the clock input terminal of the dual pull-down control module is connected to the first clock input terminal.

8. The shift register unit according to claim 7, wherein the control subunit includes:
a low level input terminal;
a sixth thin film transistor, a gate of the sixth thin film transistor is connected to the first terminal of the control subunit, a first pole of the sixth thin film transistor is connected to the low level input terminal, a second pole of the sixth thin film transistor is connected to the third terminal of the control subunit; and
a seventh thin film transistor, a gate of the seventh thin film transistor is connected to the first terminal of the control subunit, a first pole of the seventh thin film transistor is connected to the low level input terminal, a second pole of the seventh thin film transistor is connected to the second terminal of the control subunit.

9. The shift register unit according to claim 7, wherein, the unidirectional turn-on element is a thin film transistor, a second pole of the unidirectional turn-on element is connected to the second pole of fifth thin film transistor, a gate and a first pole of the unidirectional turn-on element are connected to the pull-down signal output terminal; or
the unidirectional turn-on element is a diode, an anode of the diode is used as the first terminal of the unidirectional turn-on element and a cathode of the diode is used as the second terminal of the unidirectional turn-on element.

10. The shift register unit according to claim 7, wherein, the dual pull-down control module further includes a first capacitor, a first terminal of the first capacitor is connected to the second pole of the fifth thin film transistor, and a second terminal of the first capacitor is connected to the gate of the fifth thin film transistor.

11. The shift register unit according to claim 8, wherein, the dual pull-down control module further includes a first capacitor, a first terminal of the first capacitor is connected to the second pole of the fifth thin film transistor, and a second terminal of the first capacitor is connected to the gate of the fifth thin film transistor.

12. The shift register unit according to claim 9, wherein, the dual pull-down control module further includes a first capacitor, a first terminal of the first capacitor is connected to the second pole of the fifth thin film transistor, and a second terminal of the first capacitor is connected to the gate of the fifth thin film transistor.

13. The shift register unit according to claim 7, wherein the charging and resetting module includes a ninth thin film transistor, a tenth thin film transistor, a first reference voltage input terminal, and a second reference voltage input terminal, wherein:
a gate of the ninth thin film transistor is connected to the scan input terminal, a first pole of the ninth thin film transistor is connected to the first reference voltage input terminal, and a second pole of the ninth thin film transistor is connected to a first pole of the tenth thin film transistor;
a gate of the tenth thin film transistor is connected to the reset terminal, a second pole of the tenth thin film transistor is connected to the second reference voltage input terminal; and
one of the first reference voltage input terminal and the second reference voltage input terminal is a high level signal input terminal, and another one of the first reference voltage input terminal and the second reference voltage input terminal is a low level signal input terminal.

14. The shift register unit according to claim 7, wherein the output pull-down module includes a second clock input terminal and a third thin film transistor, wherein:
a gate of the third thin film transistor is connected to the second clock input terminal;
a first pole of the third thin film transistor is connected to the output terminal of the shift register unit; and
a second pole of the third thin film transistor is connected to a low level input terminal of the dual pull-down module.

15. The shift register unit according to claim 7, wherein the dual pull-down module includes a low level input terminal, a second thin film transistor, and a eighth thin film transistor, wherein:
a gate of the second thin film transistor and a gate of the eighth thin film transistor are both connected to the pull-down node; a first pole of the second thin film transistor is connected to the output terminal of the shift register unit; a second pole of the second thin film transistor is connected to the low level input terminal; and
a first pole of the eighth thin film is connected to the pull-up node; and a second pole of the eighth thin film is connected to the low level input terminal.

16. The shift register unit according to claim 7, wherein the pull-up module includes a first thin film transistor and a second capacitor, wherein:
a gate of the first thin film transistor is connected to the pull-up node; a first pole of the first thin film transistor is connected to the first clock input terminal; a second pole of the first thin film transistor is connected to the output terminal of the shift register unit; and
a first terminal of the second capacitor is connected to the pull-up node, and a second terminal of the second capacitor is connected to the output terminal of the shift register unit.

17. A gate driver, including a plurality of cascaded shift register units according to claim 7, wherein:
the scan input terminal of the shift register unit is connected to an output terminal of a shift register unit in a previous stage, and the reset terminal of the shift register unit is connected to an output terminal of a shift register unit in a next stage.

18. A display device, including the gate driver according to claim 17.
